(19) United States
(12) Patent Application Publication
(10) Pub. No.: US 2013/0001058 A1
(43) Pub. Date: Jan. 3, 2013

(54) Vehicle touch button

(75) Inventors: Mark B. Bowler, Lawrenceville, IL (US); Jared Z. Zimmerman, Bourbonnais, IL (US)

(73) Assignee: Phantom-Products LLC, Lawrenceville, IL (US)

(21) Appl. No.: 13/135,356

(22) Filed: Jul. 1, 2011

(51) Int. Cl. H03K 17/975

(52) U.S. Cl. 200/600

(57) ABSTRACT

The present disclosure relates to a touch sensitive button used in a vehicle. In one embodiment, the button is used to start the vehicle. The button may also include an illuminated area to indicate a condition of the vehicle.

### TECHNICAL FIELD

The present disclosure relates to button used in a vehicle.

### BACKGROUND

Most vehicles use buttons or switches with moving parts. Such switches may include dials, key ignitions, or push buttons that require the button to be rotated, turned, depressed, or otherwise moved to be tripped.

### SUMMARY

The present disclosure relates to a touch sensitive button used in a vehicle. In one embodiment, the button is used to start the vehicle. The button may also include an illuminated area to indicate a condition of the vehicle.

### BRIEF DESCRIPTION OF THE DRAWINGS

FIG. 1 is a perspective view from the back left of a vehicle showing a touch button.

FIG. 2 is a schematic view of an ignition system as it interacts with the vehicle of FIG. 1.

FIG. 3 is a flowchart illustrating the operation of the ignition system from FIG. 2.

FIG. 4 is a top view of the touch button from FIG. 1 being touched by a user.

FIG. 5 is an exploded top perspective view of the touch button from FIG. 1.

FIG. 6 is a cross-sectional side view of the touch button along the cross-section lines from FIG. 4.

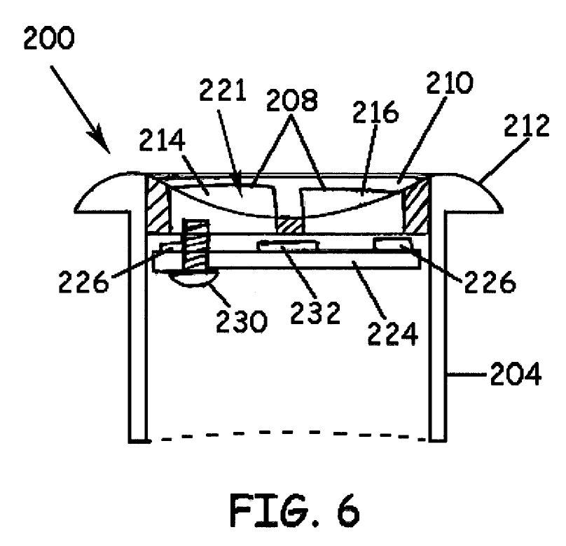

FIG. 7 is a top view showing different display patterns of the touch button.

### DETAILED DESCRIPTION

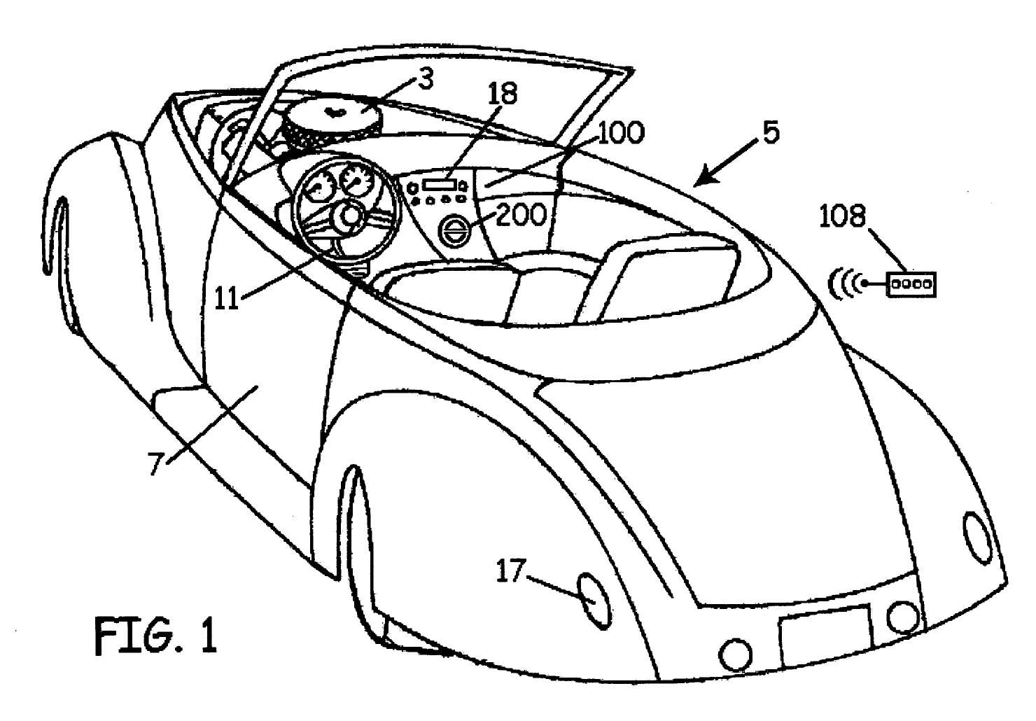

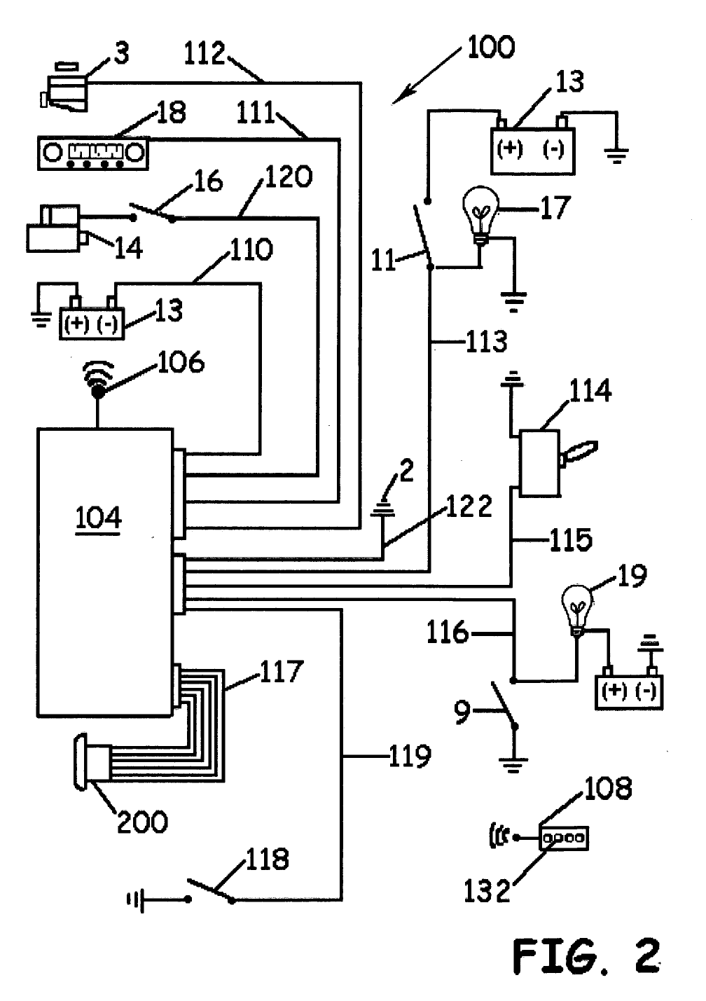

FIG. 1 illustrates a vehicle 1 and an ignition system 100 used to start the vehicle 1. FIG. 2 illustrates how the vehicle 1 and the ignition system 100 interact. The vehicle 1 may include an engine 3, interior 5, doors 7, door switch 9, brake switch 11, brake light 17, battery 13, starter 14, accessory 18, interior light 19, and neutral safety switch 16.

The engine 3 may be any device used to power the vehicle 1. The door switch 9 is any device indicating whether the operator of the vehicle 1 is inside the vehicle or getting out. The door switch 9 could be replaced by an interior light 19 or dome light or proximity detection device. The brake switch 11 is any device to indicate the operator has activated the brake 17 or that is otherwise safe to start the vehicle 1. The battery 13 is any device that provides power to the electric components. The starter 14 turns and thereby starts the engine 3. The starter 14 may not be needed if the engine 3 is replaced by a battery to power the vehicle 1, like in an electric vehicle.

The vehicle 1 is shown as a passenger car, however, the vehicle 1 may be any type of automobile or machine that is started by a user. For example, the vehicle 1 may also be a pick-up truck, work truck, tractor, ATV, motorcycle, boat, lawn mower, or anything of the like.

The ignition system 100 includes a button 200, controller 104, receiver 106, transmitter 108, accessory output 111, ignition output 112, starter output 120, connection to power supply 110, brake input 113, interior light input 116, enable input 115, secondary button input 119 and ground 2. The ignition system 100 may be keyless or may include a separate keyed feature.

In operation of the ignition system 100, the battery 13 powers the controller 104 through the power supply 110. The controller 104 includes a transistor or another device for amplifying and switching the electric signal from a microcontroller. In one embodiment, the transistor is a metal-oxide-semiconductor field-effect transistor or MOSFET.

As shown in FIG. 2, the MOSFETs inside of the controller 104 are connected to the power outputs of the controller 104 and send power to the outputs of the device. The outputs include; accessory output 111, ignition output 112, and starter output 120. The MOSFETs deliver twelve volts DC positive from the vehicles 1 battery 13.

A wire harness 117 connects the touch button 200 to the controller 104. The wire harness 117 may be a six pin harness or any other means for connecting the touch button 200 to the controller 104. The wire harness 117 supplies power to the components in the touch button 200 and facilitates communication and command between the controller 104 and the touch button 200. The other connections are inputs given to the controller 104 for operational directives. These inputs include connections to battery 13 ground 2, a positive brake input 113, a grounded enable input 115, a grounded door switch input 116, and a secondary grounded button input 119.

The connections will now be listed in detail. The battery 3 ground is shown attached to chassis ground 2 and provides a connection for the controller 104 to the battery's 13 ground 2. The brake input 113 is shown connected to the normally open side of the brake switch 11, and receives positive battery 13 voltage when the (brake pedal is depressed) brake switch 11 is closed. This connection is usually shared with the vehicles brake lights 17. The enable input 115 is shown connected to a toggle switch 114 to provide or remove ground 2 and thus enable or disable the security feature as an alternative to the wireless input. The door switch input 116 is shown connected to the normally open side of the door switch 9. The when the (door 7 opens) door switch 9 is activated, the controller 104 is provided with a ground 2.

The last input is the secondary button input 119. This input can be connected to a secondary button 118 where one of the terminals is connected to ground 2 and the other terminal is connected to the secondary button input 119, or any device capable of delivering a momentary ground 2 input. This could be an output from a car alarm or any other external device capable of delivering a momentary ground 2. This input allows operation of the controller 104 identical to that of the touch button 200 if the user wants to use the ignition system 100, but not the touch button 200. By providing a momentary ground 2 in conjunction with the other inputs of the controller 104, the controller 104 can be operated by the secondary button input 119.

The first touch of the touch button 200 is used to switch power to any accessory 18 that may be connected to the accessory power output 111. The accessory devices would usually be related to the entertainment aspect of the vehicle 1 or convenience features of the vehicle 1 such as the radio, or any multimedia devices that would connect to the radio, like a phone, amplifiers, monitor, or global positioning system, for example. The accessories 18 may also include a multi-media device, power windows, sun-roof, trunk release, etc.

The accessory output 111 is used to send power to the accessories 18. The accessories 18 connected to the accessory output 111 will be powered on during the first touch of the touch button 200, after the engine 3 is started 312, and after the engine 3 is shut off for ten minutes, or until the door switch 9 detects an opening door.

The engine 3 also includes associated ignition devices that are related to engine 3 operations or require more power to operate. These ignition devices may include; engine computer, fuel pump, air-conditioning system, gauges, etc. The ignition devices connected to the ignition output 112 will be powered on during the second touch of the touch button 200, during the engine 3 cranking cycle, and after the engine 3 is started.

The connections to the starter output 120 may include a neutral safety switch 16 (which interrupts power delivery to the starter 14 when vehicles 1 transmission is not in neutral) and the starter 14. The starter 14 and neutral safety switch 16 are only powered on during the engine 3 cranking cycle.

The purpose of powering the accessory devices 18 separately is to isolate them from other components of the vehicle 1 that are generally only needed when the vehicle 1 is being used for transportation, is to keep them from being powered on while the engine 3 is not running thus saving battery 13 power needed to start the engine 3.

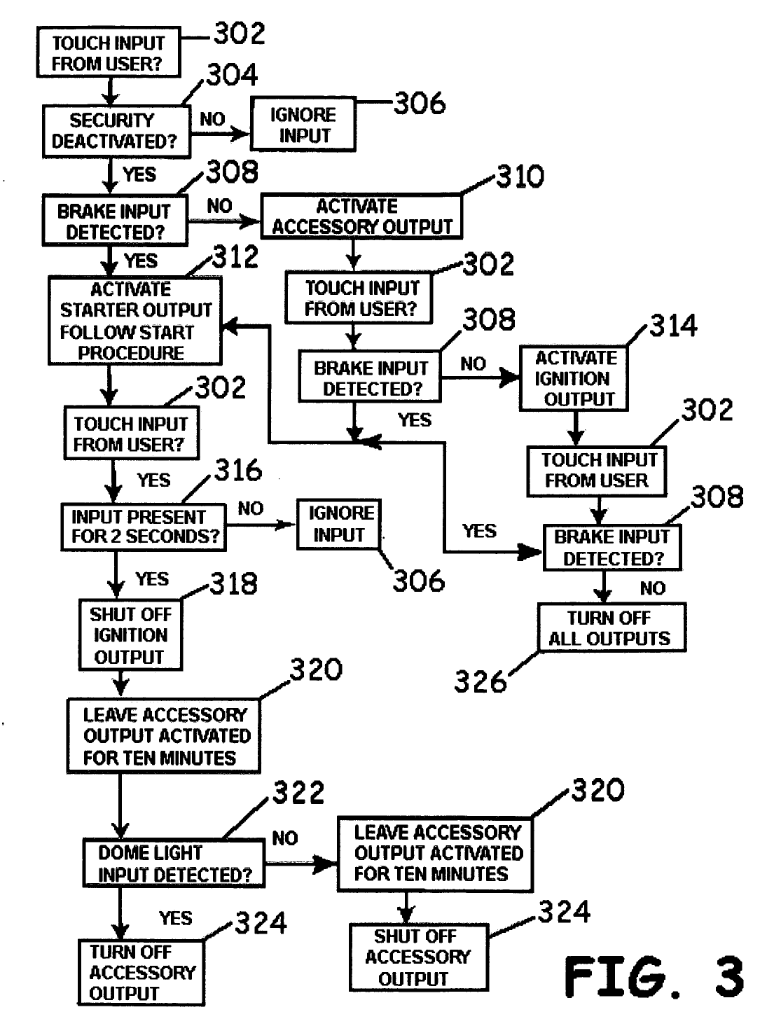

FIG. 3 shows an example of the control logic 300 the controller 104 uses. In step 302, the controller 104 sets dormant and waits for a touch input to be received from the touch button 200.

In step 304, once the first touch input is received (first touch), the controller 104 checks to see if the security is enabled. If the security is enabled, the controller 104 then will ignore the input in step 306. Adversely, if the security is disabled 304, in step 308 the controller 104 will acknowledge the input from the user, and then check for the brake input 113 for the presence of positive voltage. If positive voltage is not present, in step 310 the controller 104 will turn on the accessory output 111. Adversely, if the controller 104 detects positive voltage at the brake input 113, in step 312 the controller 104 will initiate the engine 3 start process 312 by turning on the starter output 120.

The starting process will now be described in detail and be from this point hence referred to as the starting process 312. The starting process 312 of the ignition system 100 is unique in that it allows automatic starting of the vehicles 1 engine 3. The controller 104 uses software to detect when the engine 3 is started, and then turns off the starter 14 automatically. Once a start signal is received by the controller (positive voltage at brake input 113 detected and touch input given), the starter and ignition outputs 120, 112 are turned on for three seconds, or until the engine 3 run condition is detected. If no engine 3 run is detected, the starter and ignition outputs 120, 112 are turned off. If touch input is present, for longer than three seconds however, the starting process 312 will continue for up to ten seconds. Ignition devices are also left powered on during the engine 3 starting process 312 to provide the engine 3 with what it needs to start, such as fuel, spark, and control from an engine computer where applicable.

If an engine 3 run condition is detected, the starter output 120 is turned off, the ignition output 112 is left on and five hundred milliseconds later, the accessory output 111 is turned on. The controller 104 will then wait for input from the touch button 200 given by the user.

In step 316, the input (touch) will have to be given for at least two seconds or the engine 3 will remain running. If a two second input is given by the user, the controller 104 will shut off the ignition output in step 318. In step 320, the accessory output 111 will remain on for ten minutes, or until the door switch 9 detects an opening door in step 322, upon which point the accessory output 111 will be shut off in step 324. If a second touch input is received, (once in accessory mode) but no brake input is detected, the ignition output will then be turned on in step 314.

Once the ignition output 112 is turned on in step 314 and another touch input is given (third touch), but no brake input 113 is received in step 308, all outputs will then be turned off in step 326. The ignition devices connected to the ignition power output 112 will be turned off when the engine 3 is turned off, or when the touch button 200 is changed to the off position, or upon the third touch in step 326.

If the brake input detects a positive input in step 308, the start process 312 will be initiated. Once the engine 3 is running, the controller 104 waits for a two second input from the user in step 316, then shuts off the engine 3 in step 318, leaving the accessory output turned for ten minutes in step 320, or until the door switch 9 detects and opening door in step 322.

The controller 104 also has a transmitter 108 and receiver 106 that allow both passive and active arming of the security system, and operation of the touch button controls through wireless control. The receiver 106 may use Radio Frequency Identification or RFID is used to passively arm and disarm the security feature of the controller 104. Passive and active arming are set by the user.

The receiver 106 is located in the controller 104 and detects the proximity of the transmitter 108, once the transmitter 108 is detected, it is offered a challenge by the controller 104 (asks for a large series of numbers) that was composed by the controller 104 when last in range, if the transmitter 108 answers properly, the security is disarmed and inputs from the touch button 200 or secondary button 118 (if used) will be acknowledged. If the ignition or accessory outputs 111 or 112 are activated via the touch button 200 or the secondary button 118, the challenge questions stop to preserve battery power in the transmitter 108. When the ignition and accessory outputs 111, 112 are off and for seven seconds or more, the controller 104 starts to pose a new set of challenges which are answered by the transmitter 108 every seven seconds until the transmitter 108 is out of range.

Active arming is done by depressing one of the buttons 132 on the transmitter 108. Active arming can be read by the receiver 106 from longer distances, and is a conscious choice made by the user. Arming and disarming are displayed by different styles of flashing light made visible through the illumination area 210 of the button.

The button 200 is shown in FIG. 1 installed in the center consol of the interior 5 of the vehicle 1. However, the button 200 could also be mounted in the dash, steering wheel, door, or anywhere in the vehicle 1. The touch button 200 could also be part of a separate handheld piece in communication with the vehicle such as the transmitter 108.

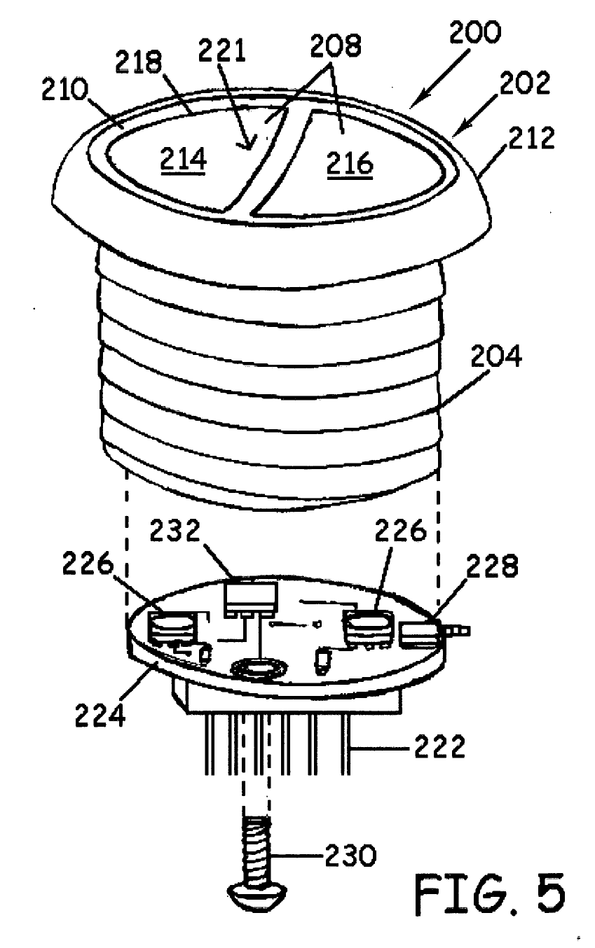

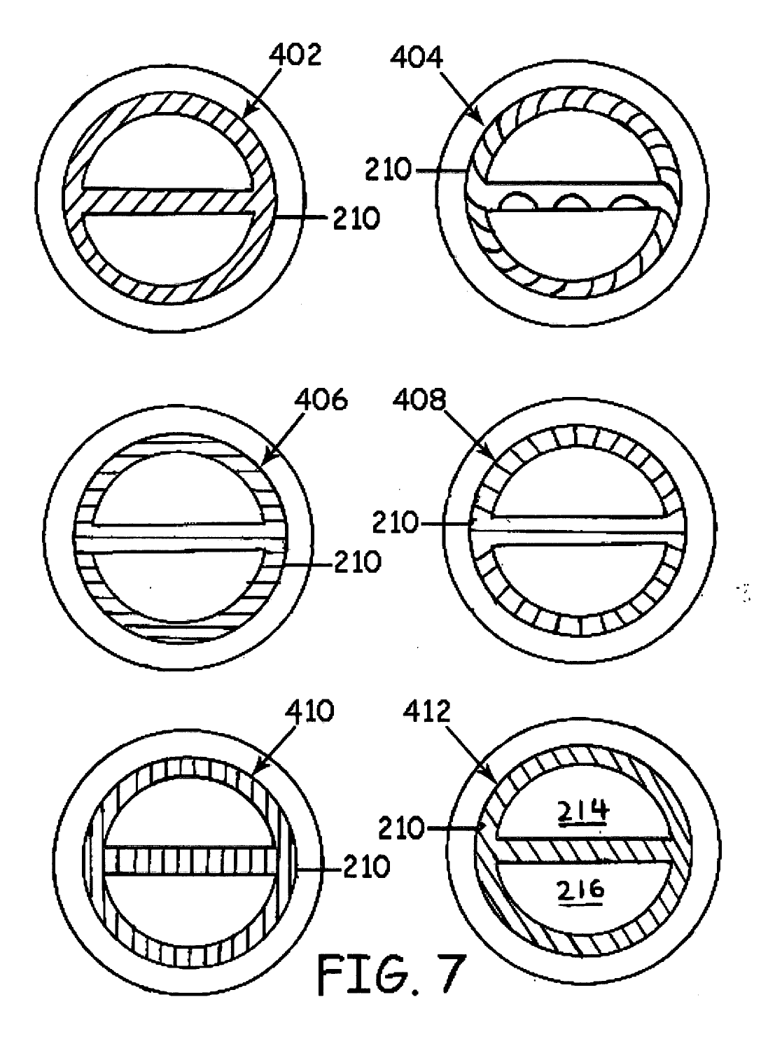

Seen best in FIG. 5, the button 200 includes a top 202, a mount 204, and a circuit board 224. The top 202 includes the contact surfaces 208 and illumination area 210 and may also include an outer rim 212. The contact surfaces 208 may include a first and second contact plate or plates 214 and 216. The illumination area 210 may include an outer band 218 going around the outer perimeter of the contact surface 208. The illumination area 210 may also include a center band 220 between the first and second contact plates 214 and 216. Seen best in FIG. 5 and the cross-section in FIG. 7, the contact surface 214 of the button 200 includes a concave curve 221 sloping downward inside from the rim 212. The concave curve is a radius of 1⅞ inches. In other embodiments, the radius could be anywhere from ½ inch to 2 inches.

The mount 204 is a structure extending down from the top 202 to mount the button 200 in the vehicle 1. The circuit board 224 may be located under the top 202 and inside the mount 204. The circuit board 224 includes a wire harness 117, circuit board 224, LEDs 226, spring contact 228, capacitive touch sensor 232, and mount screw 230.

The mount screw 230 mounts the circuit board 224 into the button 200. The spring contact 228 isolates the mount 204 and outer rim 212 from the contact surface 208. The spring contact 228 isolates the mount 204 and outer rim 212 by connecting them to the ground plane of the circuit board 224 in the button 200. This isolation keeps the touch sensor 232 located on the circuit board 224 from trying to read the density of the entire button 200 and vehicle 1 it is mounted to. Since most vehicles have more density than a human being, touch would not create enough of a change in density for the touch sensor 232 to detect. Once connected to the circuit boards 224 ground plane, the touch sensor 232 can ignore the body of the mount 204, outer rim 212, and all it is attached to, because once grounded directly, the touch sensor 232 cannot detect a change in the buttons 200 mass density, only that of the contact plates 214, 216.

The light emitting diodes or LEDs 226 may be any device to provide light. The LEDs 226 may be capable of providing light in the colors and patterns as required by the display patterns 400 described later. The illumination area 210 may consist of acrylic or another non-conductive material so light from the LEDs 226 can shine through.

The circuit board 224 powers the LEDs 226 and relays the trip signals from the button 200. The wire harness 117 allows communication with the controller 104.

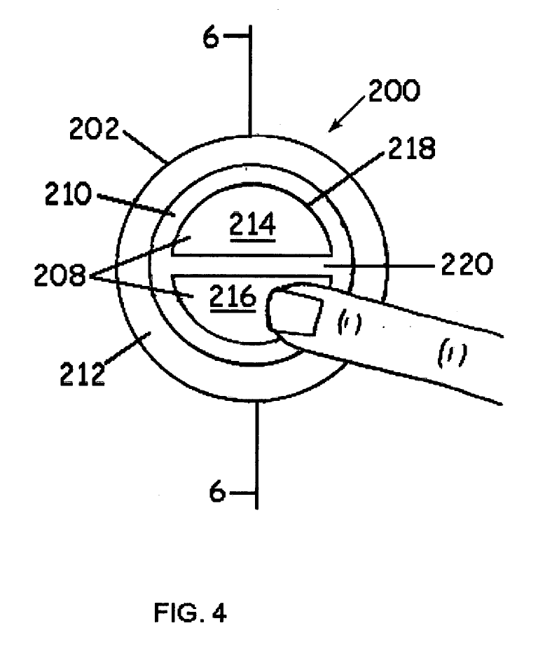

The button 200 is tripped by touch without moving parts. Said another way, the button 200 is touch-sensitive. The button 200 may be a capacitive touch button. The button 200 uses a capacitive sensitive contact surface 208 or touch sensors 232 to monitor a changing mass. Because it is capacitive sensitive, the button 200 can be tripped by a touch from any body, not just a human touch from skin. In another embodiment, a human touch is required to trip the button 200, as seen in FIG. 4.

Because aluminum is metallic with a certain density, the thickness of the contact surface 208 is kept as thin as possible while still providing shape in order to reduce mass. The smaller the mass of the contact surface 208, the easier it is for the touch sensor 232 on the circuit board 224 to detect a change in its mass density and therefore the more accurate touch detection is. Materials used in the contact surface 208 can be a variety of metallic and non metallic materials. For example if iron were used as the contact surface 208 material, the body of the contact surfaces 208 would be kept even smaller to compensate for the increase in mass density. Adversely, if a material with a less dense mass such as certain types of plastic were chosen for the material, the contact surface 208 be made larger.

When tripped, the button 200 activates or cancels power delivery to the vehicle 1, replacing the need for a conventional starting system with mechanical moving parts. The button 200 works by tying an input pin of the touch sensor 232 directly to the contact plates 214 and 216 via the mount screw 230. The touch sensor 232 employs burst of charge-transfer cycles to acquire its signal. Internally the sensor digitally processes the signal to reject impulse noise using a “consensus” filter which requires four consecutive conformations of detection before a signal is delivered. Once delivered, these signals are sent to the controller 104 via the harness 117 attached to the button 200. The controller then looks for other inputs (enable input 115, brake input 113), and carries out programming directives.

The ignition system 100 function may be influenced by variables such as large temperature fluctuations, coupling to a human body through touch, material thickness and different compositions of components. These variables affect the contact plates 214 and 216 density and thus performance of the button 200. The controller 104 was programmed to overcome these variables and provide reliable function through writing programming to cause the touch sensor 232 to check and record density every seven seconds and check those values against touch input. This way the touch sensor 232 can calculate the changing density of the contact surface 208 due to conditions such as temperature fluctuations.

The components in a standard switch usually have a tactile feel as part of the movement that indicates switch closure or opening. So, because of the touch button 200 will lack this tactile feel, the illumination area 210 is used to let the user know the button 200 has been tripped. The feedback can be provided by the illumination area 210 using different display patterns 400 as described below and seen in FIG. 7. In one embodiment the illumination area 210 provides 3 or more different display patterns 400. In another embodiment the illumination area 210 provides 4 or more different display patterns 400. In yet one embodiment the illumination area 210 provides 5 or more different display patterns 400. In other embodiments, a vibratory or sound feedback could also be provided by the button 200.

The display patterns 400 shown in FIG. 7 and described below are exemplary. A virtually endless combination of different colors and throbbing or flashing patterns could be used for any of a wide range of different conditions or states. Display pattern 402 may be a slow red throbbing to indicate the active condition of security. Display pattern 404 may be a quick flashing red light followed by a one second pause to indicate an inactive condition of security. Display pattern 406 may have a solid blue light to indicate that the controller 104 is in accessory mode (first touch), the display pattern 408 could be a solid teal light to indicate that the controller is in ignition mode (second touch). Display pattern 410 could be a solid purple light to during the starting process. Once an engine 3 run condition has been detected display pattern 412 may show the LEDs 226 illuminated a solid green color.

The illumination area 210 can also be used to communicate different states of operation to the user and can also indicate fault conditions. These fault conditions may include over current, temperatures dangerous to the circuitry and any other situation that could be potentially fatal to the circuitry of the controller 104. The LEDs 226 could rapidly alternate colors to give the user an indication of an undesirable condition in operating until the condition is no longer present for a given amount of time. At that point, the flashing lights stop and the invention will continue operating normally.

Conventional starting systems use moving parts, such as a turning key and ignition switch, pushing a button, or flipping a switch. These conventional starting systems use moving mechanical parts such as springs and levers in order to make or break contact, or electrical continuity. Because the ignition system 100 uses no or fewer moving parts may mean reduced assembly time and costs, potentially fewer parts, and improved durability.

The design of the button 200 is no longer limited to it's physical size, shape, and construction materials being such as to allow the switch to control a load because the load or loads are controlled by the controller 104, which is remotely tied to the button 200 by way of the harness 117. This is adventitious because the button does not have to be mounted adjacent to the load being controlled, nor does it have to contain large parts, which would make the button 200 physically larger. The button 200 being smaller allows for it to be mounted in a larger variety of locations. The button 200 will also never wear out due to use because there are no moving parts, or large electrical currents passing through the button 200 because the button 200 is only being used as a communication device between the user and the controller 104.

Because the design does not need to accommodate moving parts, more design options to create a start button with better aesthetics and packaging. For instance, the button size is no longer constrained due to current capability, where a switch is made large to contain parts that can handle high current switching.

Having key-less access to security allows simpler operation, instead of the user needing to have keys in hand to operate the switch. People often have many keys grouped together with their vehicle keys that put weight and strain on conventional keyed ignition tumblers, causing pre mature failures. Keys and key tumblers both wear down over time and become less compatible as well. Also drag contacts within standard keyed ignition tumblers can wear out.

The controller 104 uses MOSFET transistors that have no moving parts, and less on resistance that mechanical contacts. They have operation cycles rated at millions instead of thousands of operations. The ignition system 100 also utilizes analog inputs that can receive a momentary ground pulse and allow control of the system identical to that of the touch button 200. This means virtually any switch can be used to control the vehicles starting/ignition system.

The outer band 218 and center band 220 of the immunization area 210 may help increase the illumination area 210. Being around the contact surface 208, the outer band 218 and center band 220 may also help guide the user to intuitively know where he or she needs to touch to trip the button 200.

Containing no moving parts also increases the ability of the button 200 to operate in high stress environments with minimized malfunctions due to false triggering, such as high vibration areas. High vibration areas can cause prior art to spring into a different switch position, changing state without interaction from the user.

The curve 221 may help prevent the button 200 from being inadvertently tripped from touch because the contact surface 214 is recessed from the top most surface. The curve 221 also may also provide an ergonomic and comfortable motion or swipe from the user's finger to trip the touch button 102. The radius of curvature of the curve 221 match the approximate curve a thumb or other finger to create a natural and ergonomic feel while swiping the button 200.

Because no parts need to move relative to each other in the button 200, there is no need for gaps that would collect dirt and debris and liquids could spill into an ordinary button.

The button 200 as described herein is used in connection with an ignition system 100 to start a vehicle 1. However, the button 200 and aspects of the description above could also be applied to other functions. For instance, the button 200 could be used as a window switch or door lock with different display patterns being used to give the user feedback about the position of the window or lock. While many details are described above, the scope of this patent is defined by the claims that follow. Variations may be made and other embodiments are possible covered by these claims.

What is claimed is:

1. A button for a vehicle including:
a touch-sensitive contact surface used to trip the button;
wherein the contact surface is capacitive sensitive to activate a component of the vehicle.

2. The button of claim 1, wherein the capacitive sensitive contact surface monitors a changing mass of contact plates that will occur when touched.

3. The button of claim 1, wherein the contact surface includes two contact plates.

4. The button of claim 1, wherein the contact surface includes a contact plate with a thickness of between 1/64 inch and 3/16 inch.

5. The button of claim 1, wherein the contact surface is a concave curve.

6. The button of claim 5, wherein the concave curve has a radius between ½ inch and 2 inches.

7. The button of claim 1, wherein the contact surface is electrically isolated from the rest of the button by a spring contact so that only a change in mass of the contact surface is detected.

8. The button of claim 2, wherein the mass of the contact surface is monitored periodically to account for changing conditions.

9. A button for a vehicle including:
a touch-sensitive contact surface used to trip the button; and
an illuminated area to provide three or more different feedbacks related to three or more different conditions of the vehicle.

10. The button of claim 9, wherein the contact surface is capacitive sensitive and monitors a changing mass of contact plates that will occur when touched.

11. The button of claim 9, wherein the illuminated area is surrounding the contact surface.

12. The button of claim 9, wherein the illuminated area provides different display patterns to indicate different conditions.

13. The button of claim 12, wherein the display pattern changes as a moving transmitter comes closer to a receiver in the vehicle.

14. The button of claim 12, wherein the different display patterns include changing colors and flashing patterns.

15. The button of claim 9, wherein the contact surface includes two contact plates.

16. The button of claim 15, wherein at least a portion of the illuminated area is between the two contact plates

17. The button of claim 9, wherein the contact surface is a concave curve.

18. The button of claim 17, wherein the concave curve has a radius between ½ inch and 2 inches.

19. The button of claim 18, wherein the contact surface includes two contact plates and at least a portion of the illuminated area is between the two contact plates.

20. The button of claim 9, wherein the three or more different conditions of the vehicle include at least three of the following conditions: an active condition of security, an inactive condition of security, an accessory on mode, an ignition mode, a engine starting process, a engine run condition, and a fault condition.
